(19) United States
(12) Patent Application Publication
(10) Pub. No.: US 2026/0362703 A1
(43) Pub. Date: Nov. 12, 2026

(54) FERROELECTRIC LAYERS AND METHODS FOR THEIR MANUFACTURE

(71) Applicant: Cambridge Enterprise Limited, Cambridge Cambridgeshire (GB)

(72) Inventors: Judith Driscoll, Cambridge Cambridgeshire (GB); Nives Strkalj, Zagreb (HR); Zhuotong Sun, Cambridge Cambridgeshire (GB); Ming Xiao, Zhuhai, Guangdong (CN)

(21) Appl. No.: 19/137,995

(22) PCT Filed: Dec. 13, 2023
(86) PCT No.: PCT/EP2023/085497

§ 371 Date: Jun. 11, 2025

(30) Foreign Application Priority Data
Dec. 16, 2022 (GB) 2219088.8

(51) Int. Cl. H10B 53/30

(52) U.S. Cl. CPC H10B 53/30

(57) ABSTRACT

A device such as a memory device comprises a substrate and an active layer formed over the substrate. The active layer has a composition based on tungsten oxide (such as WO₃) and has a thickness in the range 0.5 nm to 1 μm. The active layer is anisotropically strained in relation to an equilibrium phase for the composition so as to stabilise an active layer ferroelectric phase at a temperature of 20 °C. The active layer may be epitaxial with respect to the substrate but with a lattice mismatch to provide said strain in the active layer to stabilise the active layer ferroelectric phase.

### FIELD OF THE INVENTION

The present invention relates to ferroelectric layers, devices incorporating ferroelectric layers and methods for their manufacture.

### BACKGROUND

Ferroelectric materials have a spontaneous electric polarization that can be reversed by the application of an external electric field. In a plot of applied electric field against polarisation, ferroelectric materials demonstrate a hysteresis loop. Typically, ferroelectric materials have a transition temperature referred to as the Curie temperature below which the material is ferroelectric and above which the material is paraelectric and without the capability to demonstrate spontaneous electric polarization.

Oxide films are of interest to combine with (or in the place of) silicon technology for improving processing, memory or sensing devices, e.g. for lowering operating voltage, operating at higher frequencies, operating at lower power, operating in more hostile environments, and for creating new forms of brain-like computing.

Certain oxide materials are ferroelectric materials. This has drawn interest for processing, memory and sensing devices, especially since the discovery of ferroelectricity in HfO₂ and ZrO₂ based materials. These group IV oxides have been widely studied in the last decade because they can readily be grown using chemical processes (e.g. atomic layer deposition, or other industrial deposition processes) at relatively low temperatures, i.e. they are compatible with complementary metal-oxide-semiconductor (CMOS) technology. The literature indicates that, for these materials, strain, doping, and oxygen content are important for achieving ferroelectricity. However, the ferroelectric properties of these materials are highly complex and the stabilisation of the ferroelectric phase itself is challenging because of the small difference in stabilization energy to several non-ferroelectric phases. Furthermore, devices hosting these ferroelectric binary oxides often need a wake-up process to exhibit the full polarization value and have insufficient endurance (<109 cycles) [Reference 1].

The present invention has been devised in light of the above considerations.

### SUMMARY OF THE INVENTION

Tungsten trioxide (WO₃) is a wide-bandgap semiconducting material already used in industry for gas and humidity sensors as well as in electrochromic windows. In bulk it crystallizes at room temperature in a non-polar monoclinic phase belonging to point group 2/m.

Underlying the present disclosure is a finding made by the present inventors that ferroelectricity can be stabilized in WO₃.

A ferroelectric phase has been reported in bulk crystals of WO₃ in the temperature range below 230 K (References 3, 4). The origin of this low-temperature ferroelectric phase was later attributed to defects in theoretical simulations (Reference 5). Reference 4 reports on a phase designated as ε-WO₃ using Rietveld analysis of high-resolution neutron diffraction data obtained at 15 K. The phase is described a monoclinic with space group Pc, a=5.278 Å, b=5.157 Å, c=7.665 Å, β=91.758° and Z=4.

The presence of ferroelectric phases of WO₃ is suggested in Cr-doped WO₃ nanoparticles, evidenced by a Raman response different to the one of the ground monoclinic phase, but without any direct evidence of ferroelectricity (Reference 6).

Furthermore, two works using thick (greater than 200 nm) polycrystalline films of pure and Al-doped WO₃ films use ferroelectricity as the explanation of electrochromic (Reference 7) and piezoelectric (Reference 8) properties, respectively, however without evidence of stabilization of a ferroelectric phase. In Reference 8, 225 nm thick WO₃ films were deposited using RF magnetron sputtering on sapphire substrates and annealed at 400 °C to produce Al-doped WO₃.

Strain-gradient-induced piezoelectricity, but without an indication of ferroelectricity, has been reported in thick (about 200 nm) WO₃ films grown by pulsed laser deposition (References 9,10).

It is of significant interest to develop ferroelectric materials that are suitable for use in microelectronic devices. It would be beneficial to be able to provide such materials in thin film format and using processes that are CMOS-compatible.

The present invention is based in part on the present inventors' insight that ferroelectric binary oxides other than the group IV oxides may be possible, but at the time of writing and to the best of the inventors' knowledge, there are only limited reports of ferroelectricity in such materials. References 24 and 25 are examples of such reports.

Accordingly, in a first aspect, the present invention provides a device comprising a substrate and an active layer formed over the substrate, wherein:
the active layer has a thickness in the range 0.5 nm to 1 μm;
the active layer has a composition based on tungsten oxide;
the active layer is anisotropically strained in relation to an equilibrium phase for the composition so as to stabilise an active layer ferroelectric phase at a temperature of 20 °C.

In a second aspect, the present invention provides a process for manufacturing a device comprising a substrate and an active layer, the process including the step:
forming the active layer on the substrate with a thickness in the range 0.5 nm to 1 μm, wherein the active layer has a composition based on tungsten oxide;
wherein the active layer is formed such that the active layer is anisotropically strained in relation to an equilibrium phase for the composition so as to stabilise an active layer ferroelectric phase at a temperature of 20 °C.

Optional features of the invention will now be set out. These can be combined singly or in any combination with any aspect of the invention, unless the context demands otherwise.

The active layer may have a composition based on tungsten trioxide. The composition may be expressed as MO_{3-δ}. M may include at least 90% W. M may be at least 92%, 94%, 96%, 98% or 99% W. M may additionally include one or more of: Al, Mo, Fe, Pd, Hf, Fe, Zn, Mn, Ti, Cr, Si.

Additional support for the inclusion of various elements as dopants is provided in the literature as follows:
Mo [Reference 26]
Fe [Reference 27]
Pd [Reference 28]
Hf [Reference 29]
Fe [Reference 30]
Zn [Reference 31]
Mn [Reference 32]
Ti [Reference 33]
Cr [Reference 34]
Si [Reference 35]

The incorporation of the term δ into the compositional formula is intended to take account of the possibility of non-stochiometric oxygen content or cation content, and in particular for the case of oxygen vacancies. For example, δ may be 0.1 or less.

In some embodiments, the composition of the active layer is WO₃.

In some embodiments, the active layer defines a plane which is a plane parallel to a major surface of the active layer and the active layer has a spontaneous polarization direction that is in-plane. In other embodiments, the active layer defines a plane which is a plane parallel to a major surface of the active layer and the active layer has a spontaneous polarization direction that is out-of-plane.

The strain in the active layer may be provided by an anisotropic stress in the active layer of |σ|>500 MPa. For example, the anisotropic stress in the active layer may be |σ|>600 MPa, |σ|>700 MPa, |σ|>800 MPa, |σ|>900 MPa.

The bulk crystal structure of WO₃ at room temperature is monoclinic with a=7.306 Å, b=7.540 Å, c=7.692 Å, alpha=90°, beta=90.88°, gamma=90°, with a volume of 423.7 Å³ according to Reference 4. The beta angle is less than 1° away from 90° which is difficult to resolve in typical XRD or STEM experiments. One can approximate the unit cell with a pseudo-tetragonal one to provide a useful indication of the tetragonality (the ratio between out of plane vs in-plane lattice constants). Furthermore, in the context of the present disclosure, the WO₃ films disclosed herein when formed on (110)-oriented YAlO₃ (YAO) substrate have an orthorhombic crystal structure to the precision of our XRD measurements as a, b and c are not equal. However, we cannot detect a monoclinic distortion of less than 1° and so it is acknowledged that the films could be orthorhombic with monoclinic distortion. Still further, depending on the in-plane lattice constants of the substrate, the films disclosed herein are tetragonal on (001)-oriented SrTiO₃ (STO) and (001)-oriented LaAlO₃ (LAO) (a=b on substrate and film) and orthorhombic on YAO (a and b not equal).

The composition of the active layer may be a composition that, in bulk form, has a room temperature equilibrium phase that is non-polar. It is part of the insight of the present inventors that it is unexpectedly possible to stabilise a useful ferroelectric phase using anisotropic stress even where the bulk form of the same composition would not exhibit the same ferroelectric phase.

In some embodiments, the active layer is epitaxial with respect to the substrate but with a lattice mismatch to provide said strain in the active layer to stabilise the active layer ferroelectric phase at a temperature of 20 °C. Using a lattice mismatch in this way is a convenient approach to providing the required anisotropic strain.

The substrate may have an in-plane lattice constant that is at most 99.5% of a corresponding lattice constant of the active layer material at equilibrium, thereby promoting compressive in-plane strain in the active layer. The substrate may have an in-plane lattice constant that is at most 99.0% of a corresponding lattice constant of the active layer material at equilibrium. The substrate may have an in-plane lattice constant that is at most 98.5% of a corresponding lattice constant of the active layer material at equilibrium. The substrate may have an in-plane lattice constant that is at most 98.0% of a corresponding lattice constant of the active layer material at equilibrium.

The substrate may have an in-plane lattice constant that is at least 100.5% of a corresponding lattice constant of the active layer material at equilibrium, thereby promoting tensile in-plane strain in the active layer. The substrate may have an in-plane lattice constant that is at least 101.0% of a corresponding lattice constant of the active layer material at equilibrium. The substrate may have an in-plane lattice constant that is at least 101.5% of a corresponding lattice constant of the active layer material at equilibrium. The substrate may have an in-plane lattice constant that is at least 102.0% of a corresponding lattice constant of the active layer material at equilibrium.

The active layer may be fully strained or partially relaxed. In the case where the active layer is partially relaxed, the substrate may have an in-plane lattice constant that is up to 99.9% or not less than 100.1% of a corresponding lattice constant of the partially relaxed active layer. Note that this feature can specifically be combined with the features described above in relation to the comparison of the substrate lattice constant and the corresponding lattice constant of the active layer material at equilibrium.

Furthermore, in the case where the active layer is partially relaxed, the substrate may have an in-plane lattice constant that is up to 99.5% or not less than 100.5% of a corresponding lattice constant of the partially relaxed active layer. Still further, in the case where the active layer is partially relaxed, the substrate may have an in-plane lattice constant that is up to 99.0% or not less than 101.0% of a corresponding lattice constant of the partially relaxed active layer.

The substrate may comprise a single crystalline base substrate. This is useful in particular for promoting epitaxy. The single crystalline base substrate may have at least one epitaxial buffer layer interposed between the single crystalline base substrate and the active layer. The substrate, or the buffer layer if present, may be selected from strontium titanate, lanthanum aluminate and yttrium aluminate.

The device may have an electrode layer formed between the at least one epitaxial buffer layer and the active layer. The electrode layer may itself be an epitaxial layer.

In some embodiments, the single crystalline base substrate is silicon.

The thickness of the active layer may be not more than 200 nm. For example, the thickness of the active layer may be not more than 150 nm, not more than 100 nm, not more than 80 nm, not more than 60 nm, not more than 50 nm, not more than 40 nm, not more than 30 nm, not more than 20 nm, or not more than 10 nm. The active layer may have thickness of more than 1 nm, or more than 5 nm.

The device may further comprise an overlayer formed over the active layer, so that the active layer is provided between the substrate and the overlayer. In this case, the strain in the active layer may be provided at least in part by thermally-induced strain caused by a difference in thermal expansion coefficient between the active layer and at least one of the substrate and the overlayer.

The active layer has a spontaneous (remanent) polarization value of not less than 1 μC/cm². Although it can be expected that the polarization value will depend on the thickness of the active layer, it is found that when measuring the polarization value's behaviour with thickness of the active layer, the polarization value did not reach the saturation polarization value even with WO₃ films up to 75 nm thick. Accordingly, the ranges for the polarization values in this paragraph are intended to apply for any thickness range expressed in this disclosure. The active layer may have a polarization value of not less than 1.5 μC/cm², not less than 2 μC/cm², not less than 2.5 μC/cm², or not less than 3 μC/cm².

The active layer may be deposited at a temperature of not more than 450 °C. For example, the active layer may be deposited at a temperature of not more than 440 °C, not more than 430 °C, not more than 420 °C, not more than 410 °C, or not more than 400 °C. Such temperature ranges are considered to be compatible with CMOS processes.

The active layer may be deposited at a temperature of at least 360 °C. This may assist in the epitaxial arrangement of the active layer. However, it is noted that even lower temperature may be possible, such as about 190 °C (±5 °C) [Reference 36] for example where ozone is used as oxidant. It is also possible to reduce the deposition temperature down do 150 °C (±5 °C) with the same precursor using plasma enhancement [Reference 37] and with other precursors down to 100 °C (±5 °C) [Reference 38].

The active layer may be deposited at atmospheric pressure. This is particularly useful for an industrial scale manufacturing processes since vacuum deposition equipment is not required.

The active layer may be subjected to post-deposition annealing. Such annealing may be performed in an oxidising environment (e.g. in an oxygen-rich atmosphere). The annealing temperature may be at about 400 °C (±20 °C) and maintained for some time, such as at least 1 hour, up to about 5 hours, e.g. about 3 hours. The active layer may then be cooled to room temperature. This low-temperature annealing is used to change the oxygen vacancy content in the films, not to change the crystal structure. It is considered that the oxygen vacancy content affects the free charge carrier concentration and thus the leakage current. As will be seen later, we show the change of leakage current with annealing.

In the process, the device optionally further comprises an overlayer formed over the active layer, so that the active layer is provided between the substrate and the optional overlayer. The process may include a heat treatment such that the strain in the active layer is provided at least in part by thermally-induced strain caused by a difference in thermal expansion coefficient between the active layer and at least one of the substrate and the optional overlayer.

The device may further comprise an overlayer formed over the active layer, so that the active layer is provided between the substrate and the overlayer. The process may include depositing the active layer in a polycrystalline or amorphous state, forming the overlayer in order to clamp the active layer and subsequently carrying out a post-deposition crystallisation treatment in order to crystallise the active layer, wherein the strain in the active layer is provided at least in part by difference in equilibrium density of the polycrystalline or amorphous state active layer and of the post-deposition crystallisation treatment active layer.

The active layer may be deposited in a deposition step in which high energy ions cause an anisotropic stress in the active layer of |σ|>500 MPa.

The invention includes the combination of the aspects and preferred features described except where such a combination is clearly impermissible or expressly avoided.

### SUMMARY OF THE FIGURES

Embodiments and experiments illustrating the principles of the invention will now be discussed with reference to the accompanying figures in which:

FIG. 1 shows a schematic of the crystal structure for the room temperature equilibrium bulk phase of WO₃.

FIG. 2 shows a 2θ-ω scan at (001)_{pc} position of WO₃ for films grown on a STO substrate (top), a LAO substrate (middle) and a YAO substrate (bottom).

FIG. 3 shows a reciprocal space map around the (103)_{pc} position of WO₃ for a 20 nm WO₃ film grown on STO.

FIG. 4 shows a reciprocal space map around the (103)_{pc} position of WO₃ for a 20 nm WO₃ film grown on LAO.

FIG. 5 shows a reciprocal space map around the (103)_{pc} position of WO₃ for a 20 nm WO₃ film grown on YAO.

FIG. 6 shows schematics of the equilibrium bulk phase (left hand side) and the strain-induced polar phase (right hand side) of WO₃.

FIG. 7 shows a schematic view of the heterostructure used for electrical measurements.

FIG. 8 shows a 2θ-ω scan at the (001)_{pc} position of WO₃ for a 20-nm thick CCMO buffer (black), a 20-nm thick WO₃ film (light grey) and a CCMO-WO₃ bilayer (dark grey).

FIG. 9 shows a rocking curve at 2θ=23.3° corresponding to the (001)_{pc} peak of a 20-nm thick WO₃ film grown directly on YAO.

FIG. 10 shows a reciprocal space map around the (103)_{pc} position of WO₃ showing peaks of a 20-nm thick WO₃ film and a 20-nm thick CCMO buffer.

FIG. 11 shows the film topography of a 20-nm thick WO₃ film on CCMO-buffered YAO substrate measured using atomic force microscopy (AFM).

FIG. 12 shows the PFM response of the same film as in FIG. 11 after reversible switching upon application of ±6 V of DC bias, shown in Cartesian coordinates, immediately after poling.

FIG. 13 shows the PFM response of the same film as in FIG. 11 after reversible switching upon application of ±6 V of DC bias, shown in Cartesian coordinates, after 6 hours.

FIG. 14 shows the PFM amplitude (left and side, black data points) and phase read out (right hand side, grey data points) of the same film with probing AC voltage of 2V at 32 kHz.

FIG. 15 shows the polarization value determined from current-voltage dependence in a YAO|CCMO|WO₃|Pt stack with 20-nm thick WO₃ film annealed at 400 °C for 3 h measured at 1 KHz using a ferroelectric tester.

FIG. 16 shows the endurance on repetitive cycling for the saturation polarization Ps (black data points) of the 20-nm thick WO₃ film used for FIG. 15. Also shown is the stability of the remanent polarization value 2Pr (grey data points).

FIG. 17 shows the current-voltage dependence in a YAO|CCMO|WO₃|Pt stack with 25-nm thick WO₃ film deposited at four times faster growth rate than films in FIGS. 15 and 16 as-deposited (black) and annealed at 400 °C for 5 h (grey) measured at 1 KHz using a ferroelectric tester.

FIG. 18 shows the polarization-electric-field dependence in YAO|CCMO|WO₃|Pt stacks with WO₃ film deposited at four times faster growth rate than films in FIGS. 15 and 16 annealed at 400 °C for 3 h with 25-nm (black), 50-nm (dark grey), and 75-nm (light grey) thick WO₃ films.

FIG. 19 shows the dependence of remanent polarization 2Pr on thickness of the films tested in FIG. 18.

FIG. 20 shows the PFM response of the as-grown domain configuration of the ultrathin (<10 nm) WO₃ film on CCMO-buffered YAO substrate.

FIG. 21 shows the CAFM response of the as-grown domain configuration for the film of FIG. 20.

FIG. 22 shows the CAFM response of the domain configuration for the film of FIG. 20 after reversible switching upon application of DC voltage of ±6V probed by AC voltage of 2V at the sample with an electrically grounded tip.

FIG. 23 shows the temperature dependence of the minimum area expansion coefficient of the substrate/neighboring-layer α_{S-min} needed to achieve a high anisotropic stress of σ<−500 MPa.

### DETAILED DESCRIPTION OF THE INVENTION

Aspects and embodiments of the present invention will now be discussed with reference to the accompanying figures. Further aspects and embodiments will be apparent to those skilled in the art. All documents mentioned in this text are incorporated herein by reference.

In summary, devices are disclosed comprising epitaxial WO₃ thin films that are deposited at temperatures below 400 °C using a chemical process called atmospheric pressure spatial chemical vapour deposition (AP-SCVD). The films are deposited epitaxially under close lattice-matching conditions (<4% mismatch) on oxide single crystal or buffered single crystal substrates. A new room temperature polar (ferroelectric) phase of WO₃ is engineered in the case of sufficient anisotropic stress. Also described are several exemplary approaches to achieve the anisotropic stress required for the stabilization of ferroelectricity in WO₃ films.

Tungsten trioxide, WO₃, is a wide-bandgap semiconducting material already used in the industry for gas and humidity sensors as well as for electrochromic windows. In bulk, WO₃ crystallizes at room temperature in a non-polar monoclinic phase. We show for the first time that ferroelectricity can be stabilized in WO₃ films grown at <400 C °C by AP-SCVD in epitaxial form under sufficient stress. This material has a perovskite structure and is therefore anticipated to readily grow on silicon and silicon buffered by a suitable epitaxial oxide. For example, epitaxially grown SrTiO₃ on Si has been widely established as a template system to grow epitaxial oxides [Reference 2].

Indicates of a ferroelectric phase have been reported in bulk crystals of WO₃ below room temperature (<230 K) [References 3,4]. The origin of this low-temperature ferroelectric phase was later attributed to defects in theoretical simulations [Reference 5]. The presence of ferroelectric phases of WO₃ is claimed in Cr-doped WO₃ nanoparticles, evidenced by a Raman response different to the one of the ground monoclinic phase, but without any direct evidence of ferroelectricity [Reference 6]. Furthermore, two works using thick (>200 nm) polycrystalline films of pure and Al-doped WO₃ films use ferroelectricity as the explanation of electrochromic [Reference 7] and piezoelectric [Reference 8] properties, respectively, however without evidence of stabilization of the ferroelectric phase. Strain-gradient-induced piezoelectricity, but without claims of ferroelectricity, has been reported in thick (about 200 nm) WO₃ films grown by pulsed laser deposition [References 9,10].

These reports discussed above either do not provide evidence of ferroelectricity, are not in thin film systems and/or are not produced with a CMOS-compatible method.

For industrial use, it is preferred that oxide materials are grown using CMOS-compatible methods. These methods include chemical processes and sputtering. In one implementation, the present disclosure provides the use of the AP-SCVD method to deposit the thin film. Previously, atomic layer deposition (ALD), an industry-compatible process was used to grow perovskite LaNiO₃ on oxide substrates [Reference 11]. However, ALD is a vacuum process, significantly different from the AP-SCVD atmospheric process.

In order to prepare suitable example devices, epitaxial thin films of WO₃ (3-75 nm) were deposited in open atmosphere at low temperatures in order to engineer ferroelectricity mediated by anisotropic stress. Further details are set out below.

Epitaxial WO₃ films were deposited in open atmosphere at low temperatures (below 400 °C) using atmospheric pressure chemical vapour deposition (AP-SCVD) on single crystal oxide substrates under lattice-matching conditions (<4% mismatch). The precursor chemical for the process is W[CO]₆.

The in-plane strain in the films can be tuned from tensile to compressive depending on the lattice parameters of the substrate.

The concentration of charge carriers in the WO₃ films is determined by the concentration of oxygen vacancies which in turn is controlled by the deposition rate and post-deposition annealing in O₂ at temperatures below 400 °C.

For films under in-plane compressive strain, a metallic buffer layer is used on the substrate to allow for electrical measurements.

We locally observe reversibly switchable polar domains and piezoelectric hysteresis loops in WO₃ films under in-plane compressive strain.

We show the presence of remanent polarization in a polarization hysteresis loop upon electric-field application in WO₃ films under in-plane compressive strain.

We also show polarization-controlled resistive switching in devices hosting ultrathin WO₃ films.

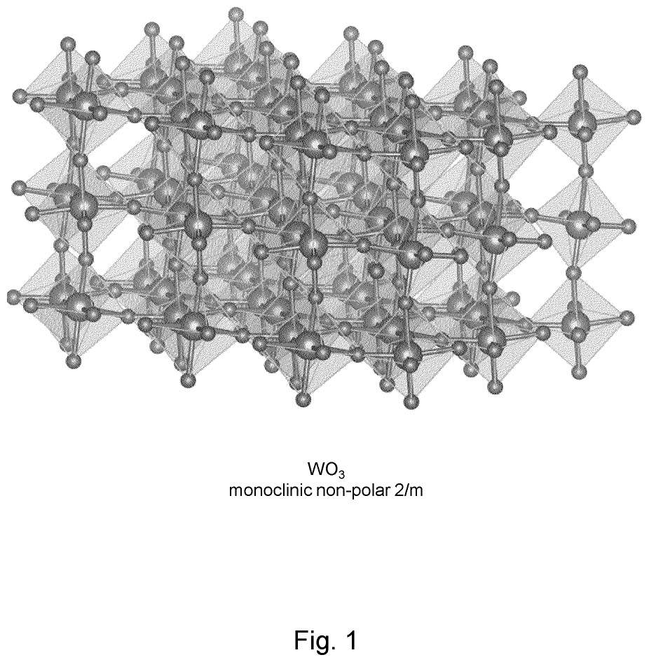

FIG. 1 shows a schematic of the crystal structure for the room temperature equilibrium bulk phase of WO₃. The crystal structure is monoclinic non-polar 2/m. The lattice parameters are a=3.85 Å, b=3.77 Å, c=3.65 Å. Considering the lattice as pseudocubic (pc), the lattice parameter would be expressed as a_{pc}=3.76 Å. FIG. 1 indicates the arrangement of WO₆ octahedra in the structure. Part of the insight of the present inventors is that an epitaxial thin film of WO₃ can be formed on a substrate with low but non-zero lattice mismatch in order to impose anisotropic strain (and therefore also anisotropic stress) on the WO₃ in order to stabilise the ferroelectric phase. In some of the embodiments described, the WO₃ can be deposited by AP-SCVD.

In order to impose a high tensile strain (3.6%) on an epitaxial thin film of WO₃, a suitable substrate is (001) SrTiO₃ with lattice parameter a=3.9 Å.

In order to impose a moderate tensile strain (1.6%) on an epitaxial thin film of WO₃, a suitable substrate is (001) LaAlO₃ with lattice parameter a=3.82 Å.

In order to impose a compressive strain (−1.6%) on an epitaxial thin film of WO₃, a suitable substrate is (001)_{pc} YAlO₃ with lattice parameter a_{pc}=3.7 Å.

Using AP-SCVD in open atmosphere at 400 °C with W[CO]₆, a non-pyrophoric air-stable material, as the precursor, we deposit epitaxial films of WO₃ with a thickness up to 75 nm on oxide substrates with lattice-matching conditions. We select (001)-oriented SrTiO₃ (STO), (001)-oriented LaAlO₃ (LAO) and (110)-oriented YAlO₃ (YAO) as substrates of interest which provide 3.6%, 1.6%, and −1.6% strain, respectively, with respect to bulk monoclinic phase belonging to point group 2/m of WO₃ in the case of fully relaxed films.

Using the ab-initio simulated and experimentally measured Young's modulus value of WO₃ being E=100 GPa [References 12, 13], we find that the corresponding in-plane stress σ on the film is 3.6 GPa, 1.6 GPa, and −1.6 GPa for STO, LAO and YAO respectively.

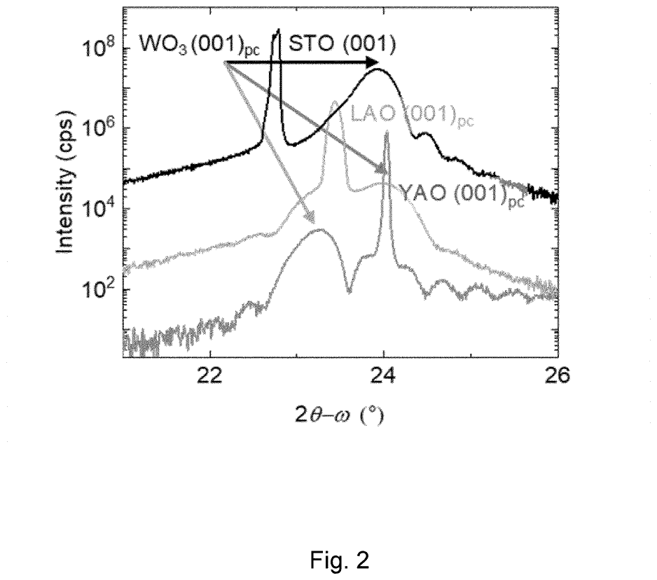

The structural characterization by x-ray diffraction for 20 nm thick WO₃ films is presented in FIG. 2, which shows a 2θ-ω scan at (001)_{pc} position of WO₃ for films grown on a STO substrate (top), a LAO substrate (middle) and a YAO substrate (bottom). For clarity, data on STO and LAO are shifted with respect to data on YAO by factors 104 and 102, respectively.

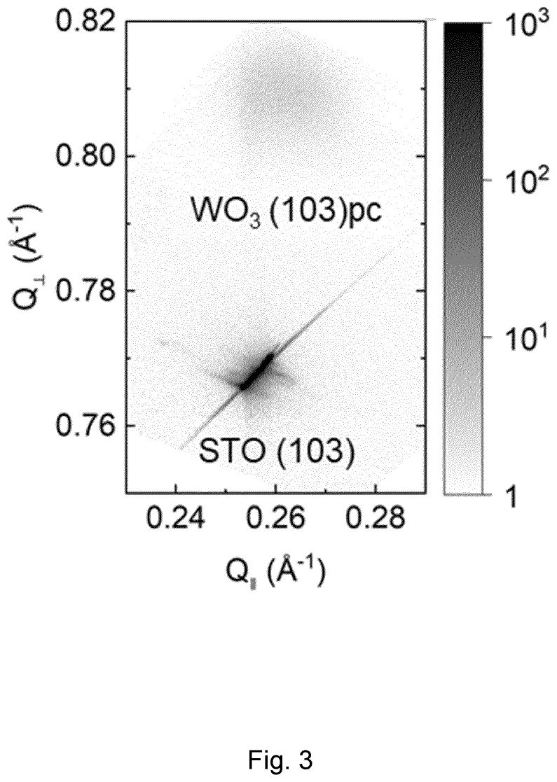

FIG. 3 shows a reciprocal space map around the (103)_{pc} position of WO₃ for a 20 nm WO₃ film grown on STO.

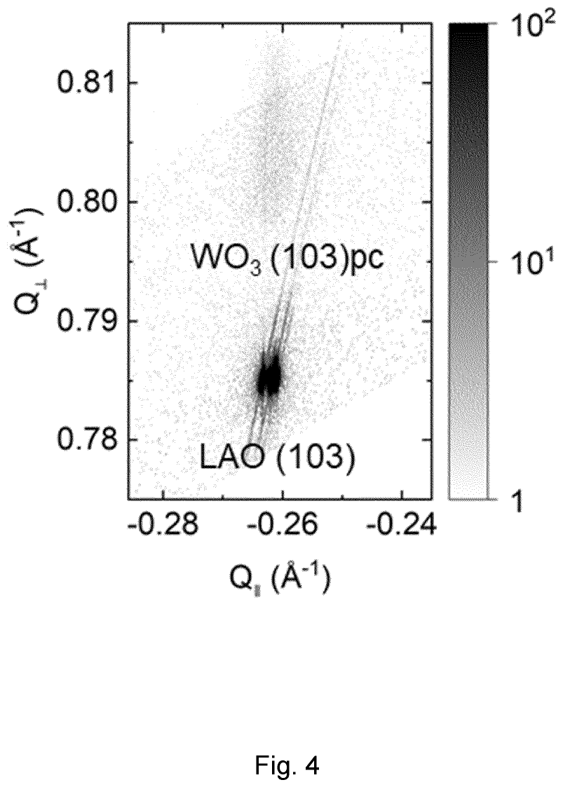

FIG. 4 shows a reciprocal space map around the (103)_{pc} position of WO₃ for a 20 nm WO₃ film grown on LAO.

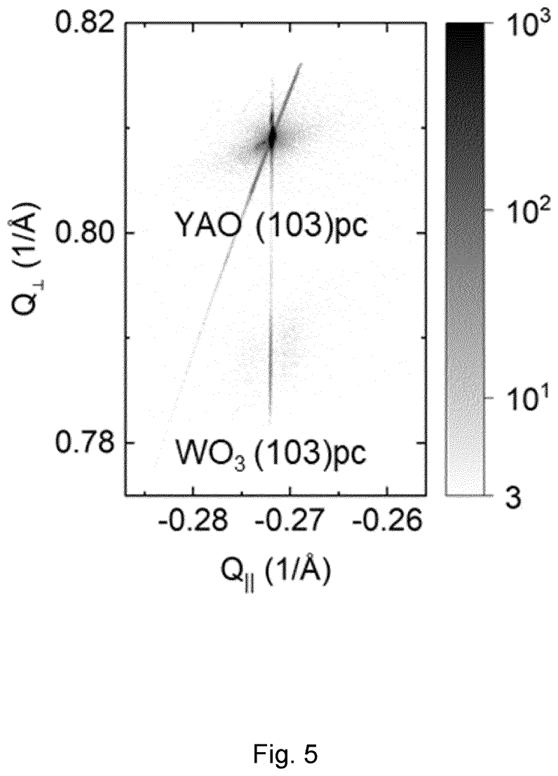

FIG. 5 shows a reciprocal space map around the (103)_{pc} position of WO₃ for a 20 nm WO₃ film grown on YAO.

At this thickness (20 nm), the WO₃ film on STO substrate is partially relaxed with in-plane lattice constants a=b=3.85±0.5 Å, c=3.71±0.2 Å.

The 20-nm thick WO₃ films are fully matched to LAO and YAO substrates, yielding a=b=3.82±0.2 Å, c=3.72±0.2 Å on LAO and a=3.68±0.1 Å, b=3.71±0.1 Å, c=3.91±0.2 Å on YAO. The lattice parameter errors are extracted from the full width at half maximum (FWHM) of WO₃ films peak intensity along Qν and Q⊥ which corresponds to about 2.355 times the standard deviation. The volume of the pseudocubic unit cells is calculated as V=abc and the error is obtained by propagation of uncertainty formula for standard deviation [Reference 14]. The unit cell volumes amount to 55±4 Å³ in STO, 54±2 Å³ in LAO, and 54±1 Å³ in YAO. In comparison, the volume of the monoclinic bulk phase amounts to 56 Å³.

We observe a large deviation of lattice parameters of WO₃ from the pseudocubic structure (c/a=1) and the bulk WO₃ structure (a/c=1.03) in WO₃ films deposited on STO (c/a=0.964) and YAO (c/a=1.057) substrates. Such a large deviation of a/c ratio from 1 opens the possibility of W ion displacement along the elongated a and c axis in the case of WO₃ films under in-plane tensile strain on STO and WO₃ films on YAO under in-plane compressive strain, respectively.

We thus propose that the tetragonality enhancement under anisotropic stress would lead to the stabilization of a ferroelectric phase in WO₃.

For WO₃ films under in-plane tensile strain on STO, polarization would be in the sample plane which makes its measurement challenging. We have evidence of stabilization of a ferroelectric phase on STO and therefore it will be possible to evaluate the ferroelectric properties.

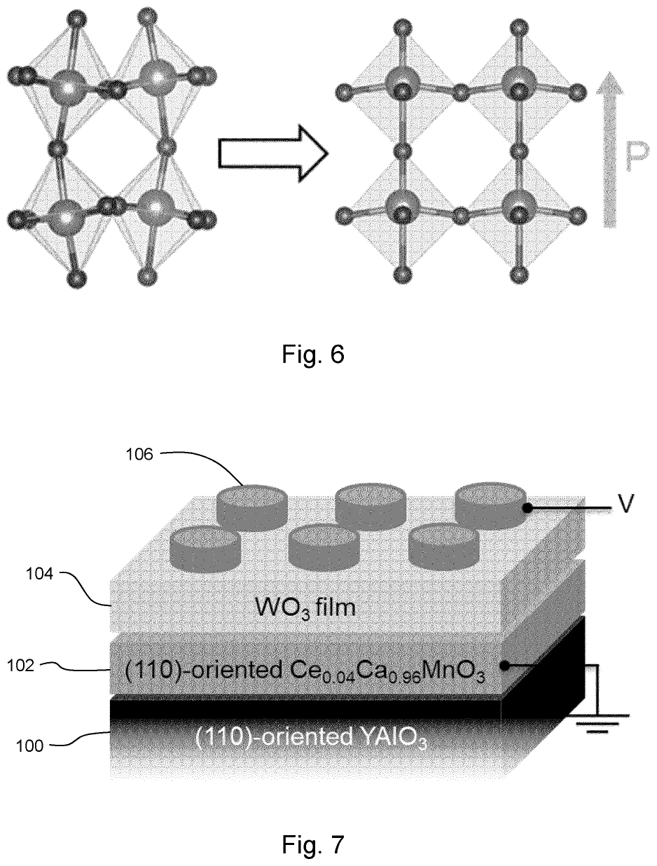

For WO₃ films under in-plane compressive stress on YAO, polarization would be out of the sample plane which facilitates its measurement. Accordingly, we introduce a metallic buffer layer to the substrate to allow for electrical measurements of polarization. A 20-nm thick Ce_{0.04}Ca_{0.96}MnO₃ (CCMO) film with close lattice matching to the YAO substrate is chosen as the buffer layer to maintain the lattice matching in the WO₃ film. A schematic of the strain-induced polar phase is shown in FIG. 6, with the left-hand image showing the equilibrium bulk phase and the right-hand image showing the strain-induced polar phase and the direction of polarisation P out of plane.

FIG. 7 shows a schematic view of the heterostructure used for electrical measurements with the YAO substrate 100, the 20-nm thick CCMO film 102 formed on the YAO substrate and connected to ground and the WO₃ film 104 formed over the CCMO film and with top electrodes 106 formed on the upper surface of the WO₃ film 104.

Films on the CCMO-buffered YAO substrate are of excellent crystalline quality with a lateral crystallite size of 350 nm. The in-plane lattice constants of both CCMO and WO₃ are still constrained to the in-plane lattice constants of the underlying YAO substrate, as now further described.

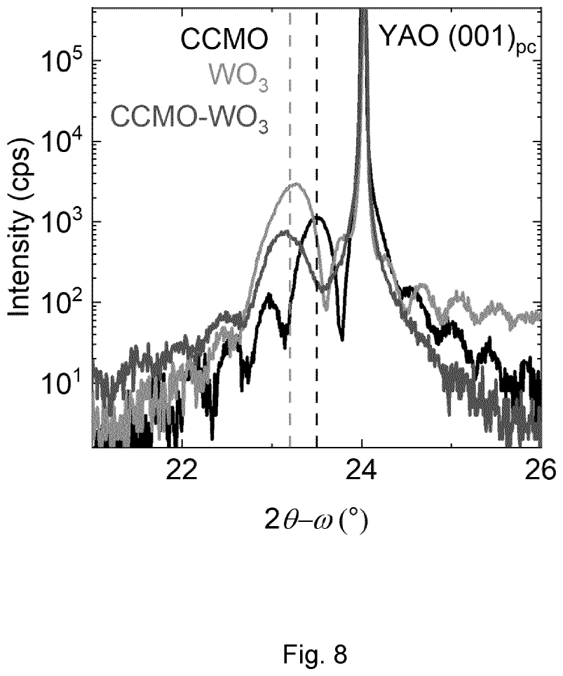

FIG. 8 shows a 2θ-ω scan at the (001)_{pc} position of WO₃ for a 20-nm thick CCMO buffer (black), a 20-nm thick WO₃ film (light grey) and a CCMO-WO₃ bilayer (dark grey).

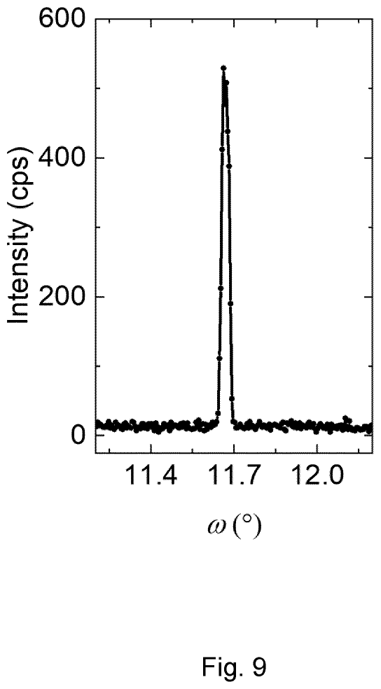

FIG. 9 shows a rocking curve at 2θ=23.3° corresponding to the (001)_{pc} peak of a 20-nm thick WO₃ film grown directly on YAO.

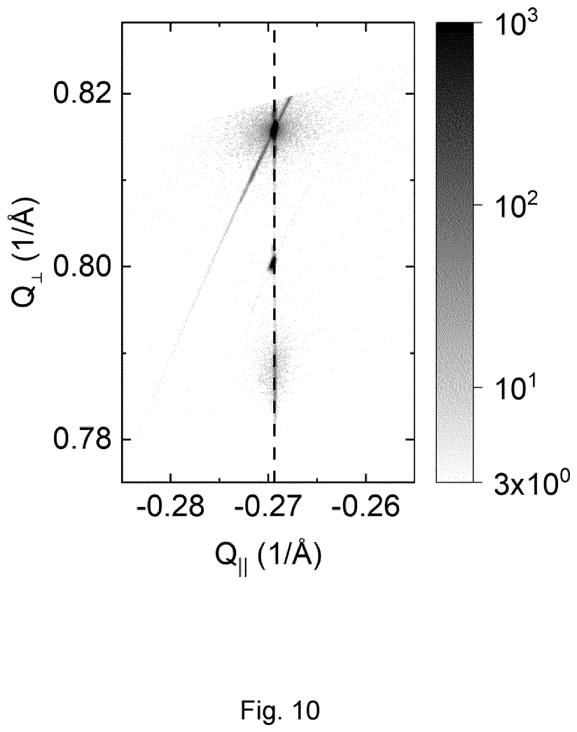

FIG. 10 shows a reciprocal space map around the (103)_{pc} position of WO₃ showing peaks of a 20-nm thick WO₃ film and a 20-nm thick CCMO buffer.

Following the stabilization of epitaxial WO₃ films on the CCMO-buffered YAO, we verify that the new phase is ferroelectric using vertical piezoresponse force microscopy (PFM). At first instance, we observe the presence of two polarization states in the as-grown films. These polarization states can be reversibly switched using an electric field applied between the PFM tip and the buffer CCMO layer. Furthermore, the switched polarization states have been maintained for more than 6 h, suggesting non-volatile nature of these states for memory applications. Local PFM loops in phase and amplitude further confirm the presence of ferroelectricity in our WO₃ thin films.

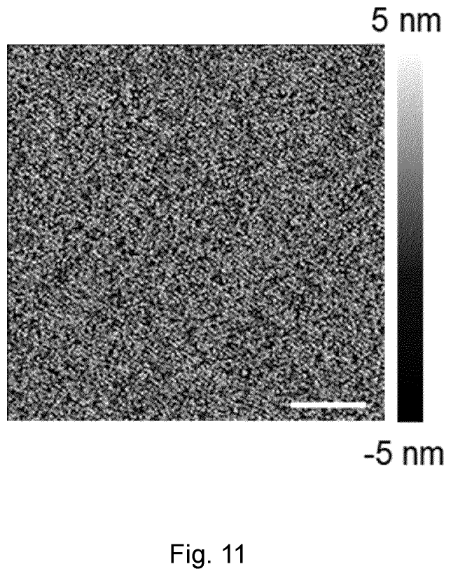

FIG. 11 shows the film topography of a 20-nm thick WO₃ film on CCMO-buffered YAO substrate measured using atomic force microscopy (AFM).

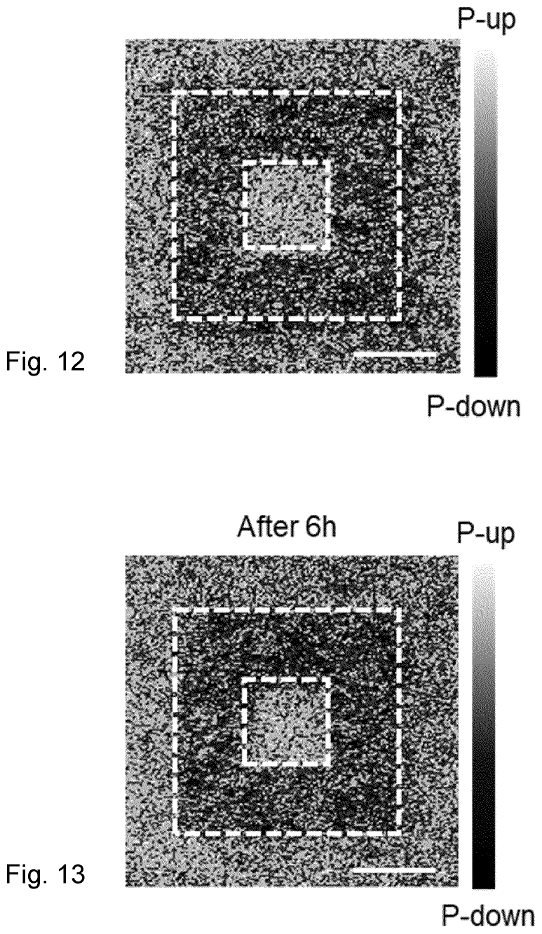

FIG. 12 shows the PFM response of the same film as in FIG. 11 after reversible switching upon application of ±6 V of DC bias, shown in Cartesian coordinates, immediately after poling. FIG. 13 shows the PFM response after 6 hours.

Note that the scale bar in FIGS. 11-13 is 1 μm.

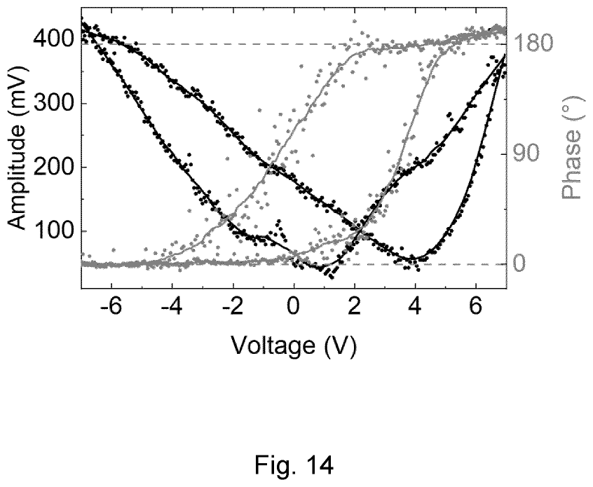

FIG. 14 shows the PFM amplitude (left and side, black data points) and phase read out (right hand side, grey data points) of the same film with probing AC voltage of 2V at 32 KHz.

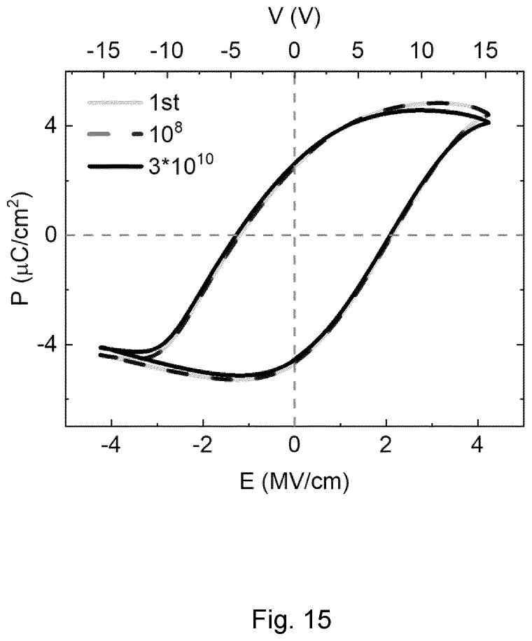

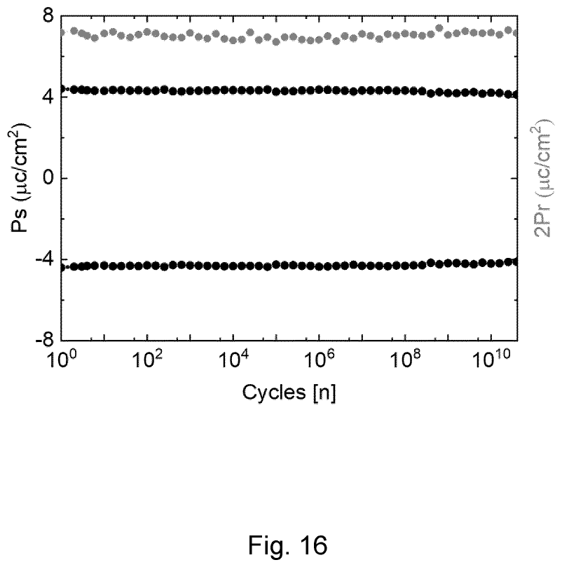

The films were patterned using UV lithography and subsequently sputtered with Pt (100 nm) to create top electrodes of 25-500 μm in diameter for ferroelectric testing. The results are described with reference to FIGS. 15 and 16.

The remanent polarization value Pr in 20-nm thick WO₃ films deposited at growth rate of 0.0083 nm/cycle annealed at 400 °C for 3 h is measured to be about 2Pr=8 μC/cm². This polarization value is comparable to initial reports of polarization in other binary oxides and sufficient for memory applications. Furthermore, the remanent polarization of the 20-nm thick WO₃ films is stable for more than 10¹⁰ switching cycles.

FIGS. 15 and 16 show the results of ferroelectric testing of WO₃ films on CCMO-buffered YAO substrate.

FIG. 15 shows the polarization value determined from current-voltage dependence in a YAO|CCMO|WO₃|Pt stack with 20-nm thick WO₃ film annealed at 400 °C for 3 h measured at 1 KHz using a ferroelectric tester.

FIG. 16 shows the endurance on repetitive cycling for the saturation polarization Ps (black data points) of the 20-nm thick WO₃ film used for FIG. 15. Also shown is the stability of the remanent polarization value 2Pr (grey data points).

Post-deposition annealing was conducted in a tube furnace with flowing oxygen (30 sccm) at a set of temperatures between 300 °C and 400 °C for 3 h to 5 h with the goal of reducing the amount of oxygen vacancies and thus reducing free charge carriers (leakage) which are associated with those vacancies. We found a suitable annealing condition of 400 °C for 5 h to reduce the leakage current by up to four orders of magnitude. Under these annealing conditions, we find that the remanent polarization increases with film thickness and no saturation polarization is found up to the thickness of 75 nm. Equivalent polarization loops and the same thickness trend was observed also for W top electrodes.

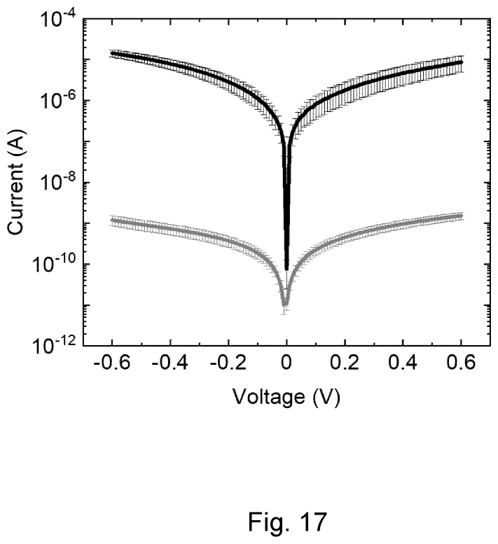

FIGS. 17-19 show the annealing and polarization-thickness dependence of WO₃ films on CCMO-buffered YAO substrate deposited at a growth rate of 0.033 nm/cycle which is four times faster than the growth rate of films in FIGS. 15 and 16.

FIG. 17 shows the current-voltage dependence in a YAO|CCMO|WO₃|Pt stack with 25-nm thick WO₃ film as-deposited (black) and annealed at 400 °C for 5 h (grey) measured at 1 KHz using a ferroelectric tester.

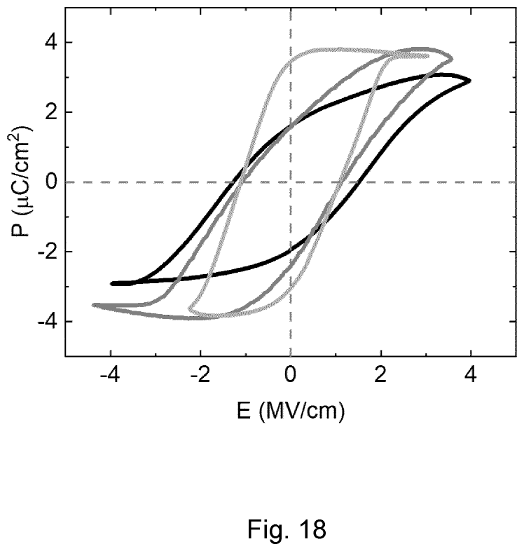

FIG. 18 shows the polarization-electric-field dependence in YAO|CCMO|WO₃|Pt stacks annealed at 400 °C for 3 h with 25-nm (black), 50-nm (dark grey), and 75-nm (light grey) thick WO₃ films.

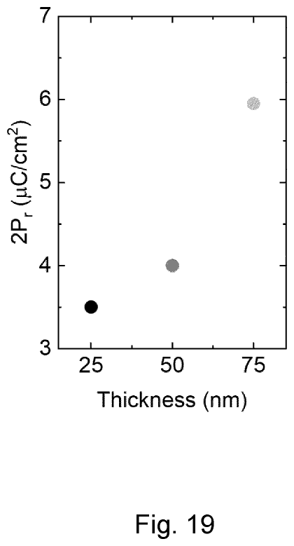

FIG. 19 shows the dependence of remanent polarization 2Pr on thickness of the films tested in FIG. 18.

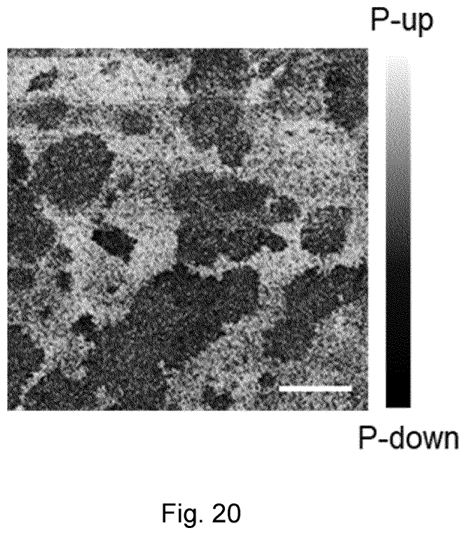

In heterostructures hosting ultrathin <10 nm thick WO₃ films, we further observe a polarization-controlled resistive switching by conductive atomic force microscopy (CAFM), i.e. that different polarization directions lead to different resistance states in the CCMO|WO₃|Pt/Ir-tip stack. This is illustrated by the results shown in FIGS. 20-22 which show resistive switching in ultrathin WO₃ films on CCMO-buffered YAO substrate.

FIG. 20 shows the PFM response of the as-grown domain configuration of the ultrathin (<10 nm) WO₃ film on CCMO-buffered YAO substrate.

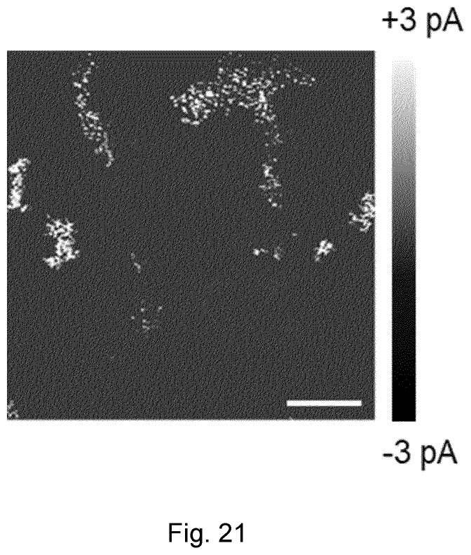

FIG. 21 shows the CAFM response of the as-grown domain configuration for the film of FIG. 20.

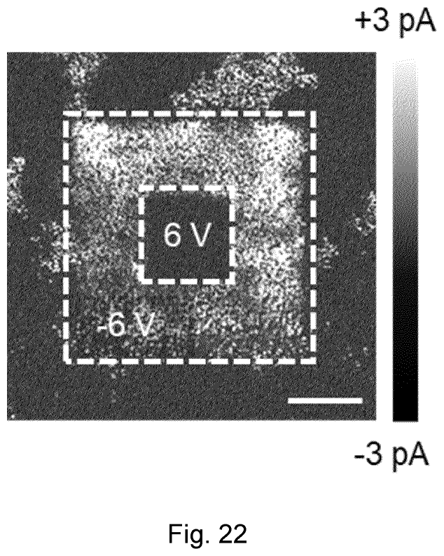

FIG. 22 shows the CAFM response of the domain configuration for the film of FIG. 20 after reversible switching upon application of DC voltage of ±6V probed by AC voltage of 2V at the sample with an electrically grounded tip.

Note that the scale bar in FIGS. 20-22 is 1 μm.

Based on the results of these experiments, the ratio in resistance of areas with polarization directions up and down is found to be more than 500 which is sufficient for memory applications.

In the experiments and analysis described above, the stress in the WO₃ films is engineered based on lattice mismatches in epitaxial films.

We engineer ferroelectricity in WO₃ films by high anisotropic stress (|σ|>500 MPa) imposed by epitaxial lattice-matching. The anisotropic stress induces high tetragonality in WO₃ films promoting ionic displacement in the long-axis direction and thus the occurrence of polarization. We conclude that anisotropic stress in general plays the dominant role in achieving ferroelectricity because the remanent polarization value increases with film thickness. In contrast, the specific film environment and interfacial phenomena play only a minor role in achieving ferroelectricity because the remanent polarization value would be constant or decrease with increasing thickness under their influence. Therefore, imposing the same anisotropic stress levels by other approaches to epitaxial lattice-matching are also expected to result in the stabilization of ferroelectricity in WO₃ films. We note that the residual anisotropic stress in WO₃ films obtained without intentional engineering is typically less than 100 MPa which is severalfold lower than the required stress to induce ferroelectricity [Reference 13].

We now describe alternative approaches to engineering anisotropic stress into such films.

Anisotropic stress can alternatively result, for example, from (i) dimension/density change under temperature cycling and (ii) high-energy ion peening/diffusion during deposition.
(i) Under temperature cycling, many processes can contribute to anisotropic stress such as a dimensional change as a result of different thermal expansion coefficients of the film and the substrate/neighbouring layer. A density change can be a result of re/crystallization in a confined volume [References 15-17].
(i-a) We considered here a difference in the thermal expansion coefficient of a WO₃ layer compared to a substrate/neighbouring layer. When WO₃ films are deposited or recrystallized at elevated temperature on substrates/neighbouring layers with thermal expansion coefficients different to the thermal expansion coefficient of WO₃, cooling the films to room temperature will result in residual stress. Since the top interface of the film is free, the thickness of the film can change during the cooling process, while the in-plane area of the film is fixed to the in-plane area of the substrate resulting in anisotropic stress. The amount of residual stress can be determined in relation to the areal thermal expansion coefficient of the substrate/neighbouring layer and temperature change. During deposition or recrystallization at elevated temperature, the area of the WO₃ film and area of the substrate/neighbouring-layer are the same. After cooling to room temperature, the area of a freestanding WO₃ film would be different that the final area of the substrate/neighbouring-layer, but the WO₃ film is strained to the substrate area.

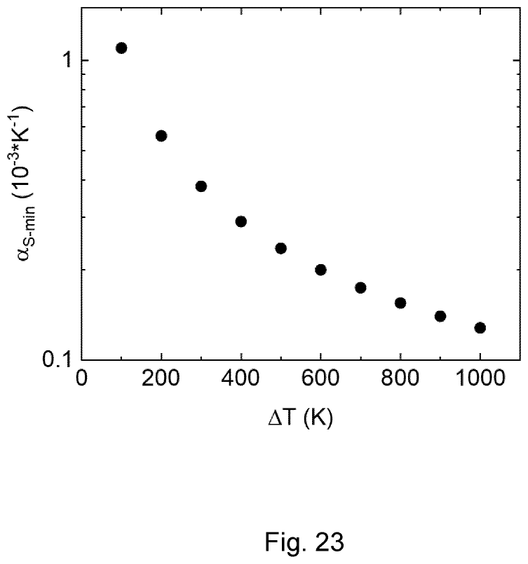

The resulting anisotropic stress in the film is:

$$σ = E * ( \sqrt{( 1 + {α}_{A} * Δ T ) / ( 1 + {α}_{S} * Δ T )} - 1 )$$

where E is the Young's modulus, α_{A}=0.8*10⁻⁵ K⁻¹ is the areal expansion coefficient of WO₃, α_{S} is the area expansion coefficient of the substrate/neighboring-layer, and ΔT is the temperature difference between deposition/annealing temperature and final temperature. To achieve the high anisotropic stress of |σ|>500 MPa considered to be suitable for stabilizing the ferroelectric phase, the α_{S} for specific temperature difference ΔT needs to be higher than the α_{S-min} value calculated in FIG. 23

FIG. 23 shows the temperature dependence of the minimum area expansion coefficient of the substrate/neighboring-layer α_{S-min} needed to achieve a high anisotropic stress of σ<−500 MPa.
(i-b) We considered here a difference in density after thermal cycling. An amorphous or polycrystalline WO₃ film with density ρ₁ can be deposited at low temperature and then covered by a top layer to clamp the thickness of the film. After heating the sample above crystallization temperature and cooling, the density of the WO₃ film changes to ρ₂. Since the thickness of the film remains constant, the change in density results in in-plane compressive stress in case of ρ₂ smaller than ρ₁, and in in-plane tensile stress in case of ρ₂ larger than ρ₁ [Reference 16]. For grains with a circular cross section, the resulting anisotropic stress under thermal cycling can be expressed as:

$$σ = E * ( \sqrt{{ρ}_{1} / {ρ}_{2}} - 1 )$$

To achieve the high anisotropic stress of |σ|>500 MPa considered to be suitable for stabilizing the ferroelectric phase, the density change needs to exceed 10%, i. e. |(ρ₂−ρ₁)/ρ₁|>10%.
(ii) Deposition with ions of high energy is known to introduce residual stress in films deposited using pulsed laser deposition and sputtering. Tensile stress can be generated at the grain boundaries due to attraction between grains and is typically inversely proportional to the square root of average grain size. Compressive stresses can be generated by atomic peening into the growing film or adatom diffusion into space between grains leading to film densification.
(ii-a) We considered pulsed laser deposition. In pulsed laser deposition, a plasma of ions is ablated from the source material with an excimer laser and deposited onto a substrate. Ion irradiation can be controlled by the excimer laser fluence and oxygen background pressure with higher fluence and lower pressure leading to ions with higher energy. In BaTiO₃ films with equivalent Young's modulus to WO₃ films, critical values of minimum excimer laser fluence of 1.5 J/cm² [Reference 18] or maximum oxygen background pressure of 50 mTorr [Reference 19] were empirically found to introduce ion-irradiation strain of |ε|>0.5% corresponding to stress levels of |σ|>500 MPa.
(ii-b) We considered sputtering. In sputtering, ion irradiation depends on the background pressure, plasma density, and electric-field application between the plasma and the substrate or between the source material and the substrate. By applying a negative potential (bias) to substrates, the Ar⁺ gas ions which are mainly used to ignite and sustain plasma, can create stress by continuously bombarding the growing film. The average energy of ions bombarding the growing film in magnetron sputtering is:

Eᵢ=E₀+nₑ·(Vₛ−V_{P})

where E₀ is the average energy of ions, n is the ion charge state, Vₛ is the applied substrate potential, and V_{P} is the plasma potential. Energy of ions bombarding the growing film can thus be easily controlled by the amplitude of the substrate potential Vₛ.

A different way to achieve this effect in case of heavy atoms such as W is to use high-power impulse magnetron sputtering (HiPIMS). In comparison to ion-assisted sputtering that refers to sputtering using Ar⁺-ion irradiation, W-ion irradiation in HiPIMS results in metal ions incorporating into the lattice sites and providing anisotropic residual stress. In HfO₂ films with similar Young's modulus to WO₃ (1.5 times larger), residual stresses higher than |σ|>500 MPa and up to several GPa are easily obtainable using an O/Ar ratio of less than 0.3 [Reference 20], Vₛ>60 V [Reference 21] or deposition-averaged target power densities higher than 30 W*cm⁻² in HiPIMS [Reference 22].

Measuring anisotropic stress. It is relatively straightforward to measure anisotropic stress in polycrystalline and amorphous thin films [Reference 23].

For polycrystalline films, an XRD-based sin² ψ method is employed to measure residual stress. It is based on the determination of a set of lattice spacings

$${d}_{ψ}^{hkl}$$

using Bragg's law from measuring Bragg's angle positions

$${θ}_{ψ}^{hkl}$$

of reflections hkl at various tilt angles ψ and azimuth angles φ. In the absence of shear stress components, the bi-axial in-plane stress can be readily extracted from the slope of

$${d}_{ψ}^{hkl} - {sin}^{2} ψ ,$$

according to a fundamental equation of x-ray residual stress analysis for stresses in the range of 10 MPa to several GPa.

For amorphous films, wafer curvature measurements can be related to residual stress using the Stoney's equation. For example, multiple-beam optical stress sensor (MOSS) technique uses the deflection of laser beams to measure the change in curvature, and thus monitor the stress in the range of 100 MPa to several GPa.

The features disclosed in the foregoing description, or in the following claims, or in the accompanying drawings, expressed in their specific forms or in terms of a means for performing the disclosed function, or a method or process for obtaining the disclosed results, as appropriate, may, separately, or in any combination of such features, be utilised for realising the invention in diverse forms thereof.

While the invention has been described in conjunction with the exemplary embodiments described above, many equivalent modifications and variations will be apparent to those skilled in the art when given this disclosure. Accordingly, the exemplary embodiments of the invention set forth above are considered to be illustrative and not limiting. Various changes to the described embodiments may be made without departing from the spirit and scope of the invention.

For the avoidance of any doubt, any theoretical explanations provided herein are provided for the purposes of improving the understanding of a reader. The inventors do not wish to be bound by any of these theoretical explanations.

Any section headings used herein are for organizational purposes only and are not to be construed as limiting the subject matter described.

Throughout this specification, including the claims which follow, unless the context requires otherwise, the word “comprise” and “include”, and variations such as “comprises”, “comprising”, and “including” will be understood to imply the inclusion of a stated integer or step or group of integers or steps but not the exclusion of any other integer or step or group of integers or steps.

It must be noted that, as used in the specification and the appended claims, the singular forms “a,” “an,” and “the” include plural referents unless the context clearly dictates otherwise. Ranges may be expressed herein as from “about” one particular value, and/or to “about” another particular value. When such a range is expressed, another embodiment includes from the one particular value and/or to the other particular value. Similarly, when values are expressed as approximations, by the use of the antecedent “about,” it will be understood that the particular value forms another embodiment. The term “about” in relation to a numerical value is optional and means for example +/−10%.

### REFERENCES

A number of publications are cited above in order to more fully describe and disclose the invention and the state of the art to which the invention pertains. Full citations for these references are provided below. The entirety of each of these references is incorporated herein.
1. Schroeder, U. et al. Impact of different dopants on the switching properties of ferroelectric hafniumoxide. Jpn. J. Appl. Phys. 53, 08LE02 (2014).
2 McKee, R. A., Walker, F. J. & Chisholm, M. F. Crystalline Oxides on Silicon: The First Five Monolayers. Phys. Rev. Lett. 81, 3014-3017 (1998).
3. Salje, E. & Viswanathan, K. Physical properties and phase transitions in WO₃. Acta Crystallogr. Sect. A 31, 356-359 (1975).
4. Woodward, P. M., Sleight, A. W. & Vogt, T. Ferroelectric Tungsten Trioxide. J. Solid State Chem. 131, 9-17 (1997).
5. Hamdi, H., Salje, E. K. H., Ghosez, P. & Bousquet, E. First-principles reinvestigation of bulk WO₃. Phys. Rev. B 94, 245124 (2016).
6. Wang, L., Teleki, A., Pratsinis, S. E. & Gouma, P. I. Ferroelectric WO₃ nanoparticles for acetone selective detection. Chem. Mater. 20, 4794-4796 (2008).
7. Abe, O. O., Jodhani, G. & Gouma, P. On the coupled ferroelectric-electrochromic effect of ε-WO₃. J. Am. Ceram. Soc. 101, 12-15 (2018).
8. Pineda-Domínguez, P. et al. Piezoelectric Response in WO₃-x Thin Films by Aluminum Clustering. preprint (2021).
9. Yun, S. et al. Flexopiezoelectricity at ferroelastic domain walls in WO₃ films. Nat. Commun. 11, 4898 (2020).
10. Yun, S. et al. Ferroelastic twin structures in epitaxial WO₃ thin films. Appl. Phys. Lett. 107, 1-6 (2015).
11. Sønsteby, H. H. et al. A foundation for complex oxide electronics-low temperature perovskite epitaxy. Nat. Commun. 11, 2872 (2020).
12. Liu, X. & Fan, H.-Q. Electronic structure, elasticity, Debye temperature and anisotropy of cubic WO₃ from first-principles calculation. R. Soc. open Sci. 5, 171921 (2018).
13. Besozzi, E. et al. Thermomechanical properties of amorphous metallic tungsten-oxygen and tungsten-oxide coatings. Mater. Des. 165, 107565 (2019).
14. https://en.wikipedia.org/wiki/Propagation_of_uncertainty.
15. Kolkovsky, V., Lukat, K., Kurth, E. & Kunath, C. Reactively sputtered hafnium oxide on silicon dioxide: Structural and electrical properties. Solid. State. Electron. 106, 63-67 (2015).
16. Fields, S. S. et al. Origin of Ferroelectric Phase Stabilization via the Clamping Effect in Ferroelectric Hafnium Zirconium Oxide Thin Films. Adv. Electron. Mater. n/a, 2200601.
17. Eckstein, U. et al. Room temperature deposition of freestanding BaTiO3 films: temperature-induced irreversible structural and chemical relaxation. J. Mater. Sci. 57, 13264-13286 (2022).
18. Damodaran, A. R., Breckenfeld, E., Chen, Z., Lee, S. & Martin, L. W. Enhancement of ferroelectric curie temperature in BaTiO3 films via strain-induced defect dipole alignment. Adv. Mater. 26, 6341-6347 (2014).
19. Jiang, Y. et al. Enabling ultra-low-voltage switching in BaTIO3. Nat. Mater. 21, 779-785 (2022).
20. Jena, S. et al. Effect of 02/Ar gas flow ratio on the optical properties and mechanical stress of sputtered HfO₂ thin films. Thin Solid Films 592, 135-142 (2015).
21. Rosemann, N. et al. Microstructure of gas flow sputtered thermal barrier coatings: Influence of bias voltage. Surf. Coatings Technol. 332, 22-29 (2017).
22. Vlček, J. et al. High-rate reactive high-power impulse magnetron sputtering of hard and optically transparent HfO₂ films. Surf. Coatings Technol. 290, 58-64 (2016).
23. Abadias, G. et al. Review Article: Stress in thin films and coatings: Current status, challenges, and prospects. J. Vac. Sci. Technol. A 36, 20801 (2018).
24. K. Ferri, S. Bachu, W. Zhu, M. Imperatore, J. Hayden, N. Alem, N. Giebink, S. Trolier-Mckinstry, J.-P. Maria, Ferroelectrics everywhere: Ferroelectricity in magnesium substituted zinc oxide thin films. J. Appl. Phys. 130, 44101 (2021).
25. F. Mezzadri, G. Calestani, F. Boschi, D. Delmonte, M. Bosi, R. Fornari, Crystal Structure and Ferroelectric Properties of ε-Ga2O3 Films Grown on (0001)-Sapphire. Inorg. Chem. 55, 12079-12084 (2016).
26. Li et al., RSC Adv., 2015, 5, 95394-95400, https://doi.org/10.1039/C5RA17098B,
27. Hui Song, Yaguang Li, Zirui Lou, Mu Xiao, Liang Hu, Zhizhen Ye, Liping Zhu, Synthesis of Fe-doped WO₃ nanostructures with high visible-light-driven photocatalytic activities, Applied Catalysis B: Environmental, Volumes 166-167, 2015, Pages 112-120, http://dx.doi.org/10.1016/j.apcatb.2014.11.020,
28. Ponnusamy et al., J. Phys. Chem. B 2018, 122, 10, 2737-2746, https://doi.org/10.1021/acs.jpcb.7b11642,
29. Kim, C., Lokhande, V., Youn, D. et al. Electrochromism in Hf-doped WO₃. J Solid State Electrochem 26, 1557-1566 (2022), https://doi.org/10.1007/s10008-022-05187-x,
30. Hui Song, Yaguang Li, Zirui Lou, Mu Xiao, Liang Hu, Zhizhen Ye, Liping Zhu, Synthesis of Fe-doped WO₃ nanostructures with high visible-light-driven photocatalytic activities, Applied Catalysis B: Environmental, Volumes 166-167, 2015, Pages 112-120, http://dx.doi.org/10.1016/j.apcatb.2014.11.020,
31. M Arshad et al., 2020 Mater. Res. Express, 7, 015407, https://doi.org/10.1088/2053-1591/ab6380,
32. Karthik, M., Parthibavarman, M., Kumaresan, A. et al. One-step microwave synthesis of pure and Mn doped WO₃ nanoparticles and its structural, optical and electrochemical properties. J Mater Sci: Mater Electron 28, 6635-6642 (2017), https://doi.org/10.1007/s10854-017-6354-3
33. He et al., Nanomaterials 2020, 10 (4), 727, https://doi.org/10.3390/nano10040727,
34. Adimule, V., Nandi, S. S., Adarsha, H. J., 2021. A Facile Synthesis of Cr Doped WO₃ Nanostructures, Study of their Current-Voltage, Power Dissipation and Impedance Properties of Thin Films. JNanoR 67, 33-42, https://doi.org/10.4028/www.scientific.net/JNanoR.67.33,
35. A. Rydosz, A. Szkudlarek, M. Ziabka, K. Domanski, W. Maziarz and T. Pisarkiewicz, “Performance of Si-Doped WO₃ Thin Films for Acetone Sensing Prepared by Glancing Angle DC Magnetron Sputtering,” in IEEE Sensors Journal, vol. 16, no. 4, pp. 1004-1012 Feb. 15, 2016, doi: 10.1109/JSEN.2015.2496212, https://doi.org/10.1109/JSEN.2015.2496212
36. Dip K. Nandi, Shaibal K. Sarkar, Atomic Layer Deposition of Tungsten Oxide for Solar Cell Application, Energy Procedia, Volume 54, 2014, Pages 782-788, https://www.sciencedirect.com/science/article/pii/S1876610214011989
37. Malm, J., Sajavaara, T. and Karppinen, M. (2012), Atomic Layer Deposition of WO₃ Thin Films using W(CO)6 and O3 Precursors. Chem. Vap. Deposition, 18:245-248, https://onlinelibrary.wiley.com/doi/epdf/10.1002/cvde.201206986
38. Balasubramanyam et al., Plasma-enhanced atomic layer deposition of tungsten oxide thin films using (tBuN)2(Me2N)2W and O2 plasma, Journal of Vacuum Science & Technology A 36, 01B103 (2018) https://avs.scitation.org/doi/full/10.1116/1.4986202

1. A device comprising a substrate and an active layer formed over the substrate, wherein:
the active layer has a thickness in the range 0.5 nm to 1 μm;
the active layer has a composition based on tungsten oxide;
the active layer is anisotropically strained in relation to an equilibrium phase for the composition so as to stabilise an active layer ferroelectric phase at a temperature of 20 °C.

2. A device according to claim 1 wherein the composition of the active layer is WO₃.

3. A device according to claim 1 or claim 2 wherein the active layer defines a plane which is a plane parallel to a major surface of the active layer and the active layer has a spontaneous polarization direction that is in-plane.

4. A device according to claim 1 or claim 2 wherein the active layer defines a plane which is a plane parallel to a major surface of the active layer and the active layer has a spontaneous polarization direction that is out-of-plane.

5. A device according to any one of claims 1 to 4 wherein the strain in the active layer is provided by an anisotropic stress in the active layer of |σ|>500 MPa.

6. A device according to any one of claims 1 to 5 wherein the composition of the active layer is a composition that, in bulk form, has a room temperature equilibrium phase that is non-polar.

7. A device according to any one of claims 1 to 6 wherein the active layer is epitaxial with respect to the substrate but with a lattice mismatch to provide said strain in the active layer to stabilise the active layer ferroelectric phase at a temperature of 20 °C.

8. A device according to claim 7 wherein the substrate has an in-plane lattice constant that is at most 99.5% of a corresponding lattice constant of the active layer material at equilibrium, thereby promoting compressive in-plane strain in the active layer.

9. A device according to claim 7 wherein the substrate has an in-plane lattice constant that is at least 100.5% of a corresponding lattice constant of the active layer material at equilibrium, thereby promoting tensile in-plane strain in the active layer.

10. A device according to any one of claims 7 to 9 wherein the active layer is fully strained or partially relaxed, wherein in the case where the active layer is partially relaxed, the substrate has an in-plane lattice constant that is up to 99.9% or not less than 100.1% of a corresponding lattice constant of the partially relaxed active layer.

11. A device according to any one of claims 7 to 10 wherein the substrate comprises a single crystalline base substrate.

12. A device according to claim 11 wherein the single crystalline base substrate has at least one epitaxial buffer layer interposed between the single crystalline base substrate and the active layer.

13. A device according to claim 12 wherein the buffer layer is selected from strontium titanate, lanthanum aluminate and yttrium aluminate.

14. A device according to claim 12 or claim 13 wherein the device has an electrode layer formed between the at least one epitaxial buffer layer and the active layer.

15. A device according to any one of claims 11 to 14 wherein the single crystalline base substrate is silicon.

16. A device according to any one of claims 1 to 15 wherein the thickness of the active layer is not more than 200 nm.

17. A device according to any one of claims 1 to 6 wherein the device optionally further comprises an overlayer formed over the active layer, so that the active layer is provided between the substrate and the overlayer,
and wherein the strain in the active layer is provided at least in part by thermally-induced strain caused by a difference in thermal expansion coefficient between the active layer and at least one of the substrate and the overlayer.

18. A device according to any one of claims 1 to 17 wherein the active layer has a spontaneous polarization value of not less than 1 μC/cm².

19. A process for manufacturing a device comprising a substrate and an active layer, the process including the step:
forming the active layer on the substrate with a thickness in the range 0.5 nm to 1 μm, wherein the active layer has a composition based on tungsten oxide;
wherein the active layer is formed such that the active layer is anisotropically strained in relation to an equilibrium phase for the composition so as to stabilise an active layer ferroelectric phase at a temperature of 20 °C.

20. A process according to claim 19
wherein the active layer is epitaxial with respect to the substrate but with a lattice mismatch to provide strain in the active layer to stabilise an active layer ferroelectric phase at a temperature of 20 °C.

21. A process according to claim 19 or claim 20 wherein the active layer is deposited at a temperature of not more than 450 °C.

22. A process according to any one of claims 19 to 21 wherein the active layer is deposited at a temperature of at least 360 °C.

23. A process according to any one of claims 19 to 22 wherein the active layer is deposited at atmospheric pressure.

24. A process according to any one of claims 19 to 23 wherein the active layer is subjected to post-deposition annealing.

25. A process according to claim 19 wherein the device optionally further comprises an overlayer formed over the active layer, so that the active layer is provided between the substrate and the optional overlayer, wherein the process includes a heat treatment such that the strain in the active layer is provided at least in part by thermally-induced strain caused by a difference in thermal expansion coefficient between the active layer and at least one of the substrate and the optional overlayer.

26. A process according to claim 19 wherein the device further comprises an overlayer formed over the active layer, so that the active layer is provided between the substrate and the overlayer, wherein the process includes depositing the active layer in a polycrystalline or amorphous state, forming the overlayer in order to clamp the active layer and subsequently carrying out a post-deposition crystallisation treatment in order to recrystallise the active layer, wherein the strain in the active layer is provided at least in part by difference in equilibrium density of the polycrystalline or amorphous state active layer and of the post-deposition crystallisation treatment active layer.

27. A process according to claim 19 wherein the active layer is deposited in a deposition step in which high energy ions cause an anisotropic stress in the active layer of |σ|>500 MPa.
